(19) United States
(12) Patent Application Publication
(10) Pub. No.: US 2025/0160147 A1
(43) Pub. Date: May 15, 2025

(54) DISPLAY DEVICE AND METHOD OF MANUFACTURING THE SAME

(71) Applicant: Samsung Display Co., LTD., Yongin-si (KR)

(72) Inventors: Dong Hyun LEE, Yongin-si (KR); Si Joon SONG, Yongin-si (KR); Dae Hyuk IM, Yongin-si (KR)

(73) Assignee: Samsung Display Co., LTD., Yongin-si (KR)

(21) Appl. No.: 18/772,536

(22) Filed: Jul. 15, 2024

(30) Foreign Application Priority Data
Nov. 9, 2023 (KR) 10-2023-0154637

(51) Int. Cl. H10K 59/131; H10K 59/12; H10K 59/124

(52) U.S. Cl. CPC H10K 59/131; H10K 59/1201; H10K 59/124

(57) ABSTRACT

A display device comprises a first substrate comprising an opening, a pad part on the first substrate and exposed through the opening, a second substrate on the pad part and comprising a first contact hole, a first connection line on the second substrate, and inserted into the first contact hole to be connected to the pad part, a second connection line in a layer between the second substrate and the first connection line and connected to the first connection line, a pixel circuit electrically connected to the second connection line, a driver substrate inserted into the opening of the first substrate, and comprising a base part below the pad part and having a side surface tapered from a top surface, and a lead line extending on a bottom surface and the side surface of the base part, and a contact portion electrically connecting the pad part to the lead line.

### CROSS-REFERENCE TO RELATED APPLICATION(S)

This application claims priority to and benefits of Korean Patent Application No. 10-2023-0154637 under 35 U.S.C. § 119, filed on Nov. 9, 2023 in the Korean Intellectual Property Office, the entire contents of which are herein incorporated by reference.

### BACKGROUND

### 1. Technical Field

The disclosure relates to a display device and a method of manufacturing the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device, or an organic light emitting display device. Among the flat panel display devices, in the light emitting display device, since each of pixels of a display panel includes a light emitting element capable of emitting light by itself, an image can be displayed without a backlight unit providing light to the display panel.

### SUMMARY

Aspects of the disclosure provide a display device and a method of manufacturing the same, which may reduce manufacturing cost by omitting a separate flexible film or flexible printed circuit board by including a driver substrate manufactured simultaneously with a display panel.

Aspects of the disclosure also provide a display device and a method of manufacturing the same, which may reduce manufacturing time and manufacturing cost by minimizing the size of the non-display area and simplifying the manufacturing process.

However, aspects of the disclosure are not restricted to those set forth herein. The above and other aspects of the disclosure will become more apparent to one of ordinary skill in the art to which the disclosure pertains by referencing the detailed description of the disclosure given below.

According to an embodiment, a display device may include a first substrate including an opening, a pad part disposed on the first substrate and exposed through the opening, a second substrate disposed on the pad part and including a first contact hole, a first connection line disposed on the second substrate, and inserted into the first contact hole to be connected to the pad part, a second connection line disposed in a layer between the second substrate and the first connection line and connected to the first connection line, a pixel circuit electrically connected to the second connection line, a driver substrate inserted into the opening of the first substrate, and including a base part disposed below the pad part and having a side surface tapered from a top surface, and a lead line extending on a bottom surface and the side surface of the base part, and a contact portion electrically connecting the pad part to the lead line.

The base part and the second substrate may contain a same material and be formed in a same process.

The display device may further include a gate insulating layer disposed on the second substrate and including a second contact hole overlapping the first contact hole, and an interlayer insulating layer disposed on the gate insulating layer and including a third contact hole overlapping the first and second contact holes. The first connection line may be inserted into the first to third contact holes to contact the pad part.

The contact portion may be formed by sintering at least one of conductive ink, metal paste, and metal organic decomposition ink, the conductive ink containing at least one of silver (Ag), copper (Cu), aluminum (Al), and chromium (Cr).

The driver substrate may further include a barrier insulating layer attached to a bottom surface of the pad part through an adhesive member, a gate insulating layer disposed on the bottom surface and the side surface of the base part, and an interlayer insulating layer disposed in a layer between the gate insulating layer and the lead line. The lead line and the first connection line may contain a same material and may be formed in a same process.

The driver substrate may further include a gate insulating layer disposed on the bottom surface and side surface of the base part, and an interlayer insulating layer disposed in a layer between the gate insulating layer and the lead line. The base part may be attached to a bottom surface of the pad part through an adhesive member, and the lead line and the first connection line may contain a same material and may be formed in a same process.

The driver substrate may further include a barrier insulating layer attached to a bottom surface of the pad part through an adhesive member. The lead line may be directly disposed on the bottom surface and the side surface of the base part, and the lead line and the first connection line may contain a same material and may be formed in a same process.

The driver substrate may further include a barrier insulating layer attached to a bottom surface of the pad part through an adhesive member, a gate insulating layer disposed on the bottom surface and the side surface of the base part, and an interlayer insulating layer disposed in a layer between the gate insulating layer and the lead line. The lead line may include a first line layer formed in a same process and containing a same material as the first connection line, and a second line layer disposed on the first line layer.

The driver substrate may further include a barrier insulating layer attached to a bottom surface of the pad part through an adhesive member, and a gate insulating layer disposed on the bottom surface and the side surface of the base part. The lead line and the second connection line may contain a same material and may be formed in a same process.

The driver substrate may further include a barrier insulating layer attached to a bottom surface of the pad part through an adhesive member, an auxiliary line disposed in a layer between the barrier insulating layer and the base part, a gate insulating layer disposed on the bottom surface and the side surface of the base part, and an interlayer insulating layer disposed in a layer between the gate insulating layer and the lead line. The lead line and the first connection line may contain a same material and may be formed in a same process, and the lead line may contact the auxiliary line.

The driver substrate may further include a barrier insulating layer attached to a bottom surface of the pad part through an adhesive member, a gate insulating layer disposed on the bottom surface and the side surface of the base part, an auxiliary line disposed on the gate insulating layer, and an interlayer insulating layer disposed on the auxiliary line. The lead line and the first connection line may contain a same material and may be formed in a same process, and the auxiliary line and the second connection line may contain a same material and may be formed in a same process.

The lead line may be inserted into a contact hole provided in the interlayer insulating layer to contact the auxiliary line, and an end of the lead line may be spaced apart from an end of the auxiliary line.

The display device may further include a first via layer disposed on the pixel circuit, a second via layer disposed on the first via layer, pixel electrodes disposed on the second via layer, and a pixel defining layer insulating the pixel electrodes. The driver substrate may further include a protective part disposed on the lead line and the interlayer insulating layer, and formed in a same process and containing a same material as at least one of the first via layer, the second via layer, and the pixel defining layer.

The driver substrate may be disposed between the lead lines, and the driver substrate may further include a partition wall formed in a same process and containing a same material as the protective part.

According to an embodiment, a method of manufacturing a display device may include preparing a first substrate, forming a pad part on the first substrate, forming a base part and a second substrate on the pad part and including contact hole, forming connection line disposed on the second substrate and inserted into the first contact hole, and a lead line disposed on the base part, etching a lower portion of the first substrate to form an opening of the first substrate exposing the pad part, and removing the first substrate supporting the base part, separating a driver substrate including the lead line and the base part by cutting along a cut line between the connection line and the lead line, inserting the driver substrate into the opening to be disposed on a bottom surface of the pad part, and forming a contact portion electrically connecting the lead line of the driver substrate to the pad part.

The method may further include forming a barrier insulating layer on the first substrate, forming a gate insulating layer on the second substrate and the base part, and forming an interlayer insulating layer on the gate insulating layer. The separating of the driver substrate may include separating the driver substrate including the barrier insulating layer, the base part, the gate insulating layer, the interlayer insulating layer, and the lead line.

The method may further include forming a gate insulating layer on the second substrate and the base part, and forming an interlayer insulating layer on the gate insulating layer. The separating of the driver substrate may include separating the driver substrate including the base part, the gate insulating layer, the interlayer insulating layer, and the lead line.

The method may further include forming a barrier insulating layer on the first substrate. The separating of the driver substrate may include separating the driver substrate including the barrier insulating layer, the base part, and the lead line.

The forming of the lead line may include forming a lead line including a first line layer disposed on the base part and a second line layer disposed on the first line layer.

The separating of the driver substrate may include separating an end of the lead line from the cut line.

In accordance with the display device and the method of manufacturing the same according to embodiments, the driver substrate manufactured simultaneously with the display panel may be included to omit a separate flexible film or flexible printed circuit board, thereby reducing manufacturing cost. Further, the display device and the method of manufacturing the same may minimize the size of the non-display area and simplify the manufacturing process, thereby reducing manufacturing time and manufacturing cost.

However, effects according to the embodiments of the disclosure are not limited to those mentioned above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic cross-sectional view illustrating a display device according to an embodiment;

FIG. 3 is a schematic cross-sectional view taken along line I-I′ of FIG. 1;

FIG. 4 is a schematic bottom view illustrating a display device according to an embodiment;

FIG. 5 is a schematic plan view illustrating a part of a non-display area of a display device according to an embodiment;

FIG. 6 is a schematic cross-sectional view illustrating a part of a display device according to an embodiment;

FIG. 7 is a schematic cross-sectional view illustrating a driver substrate of a display device according to an embodiment;

FIG. 8 is a schematic cross-sectional view illustrating a driver substrate of a display device according to another embodiment;

FIG. 9 is a schematic cross-sectional view illustrating a driver substrate of a display device according to still another embodiment;

FIG. 10 is a schematic cross-sectional view illustrating a driver substrate of a display device according to still another embodiment;

FIG. 11 is a schematic cross-sectional view illustrating a driver substrate of a display device according to still another embodiment;

FIG. 12 is a schematic cross-sectional view illustrating a driver substrate of a display device according to still another embodiment;

FIG. 13 is a schematic cross-sectional view illustrating a driver substrate of a display device according to still another embodiment;

FIGS. 14 to 19 are schematic cross-sectional views illustrating a manufacturing process of a display device according to an embodiment;

FIG. 20 is a schematic plan view illustrating an example of a cut line of a display panel and a driver substrate during the manufacturing process of a display device according to an embodiment;

FIG. 21 is a schematic plan view illustrating another example of a cut line of a display panel and a driver substrate during the manufacturing process of a display device according to an embodiment;

FIG. 22 is a schematic plan view illustrating still another example of a cut line of a display panel and a driver substrate during the manufacturing process of a display device according to an embodiment; and

FIG. 23 is a schematic plan view illustrating still another example of a cut line of a display panel and a driver substrate during the manufacturing process of a display device according to an embodiment.

### DETAILED DESCRIPTION OF THE EMBODIMENTS

Hereinafter, detailed embodiments of the disclosure are described with reference to the accompanying drawings. In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more aspects of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the scope of the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure. Like reference numerals denote like elements.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there may be no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “contains,” “containing,” “includes,” “including,” “has,” “have,” and “having”, when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

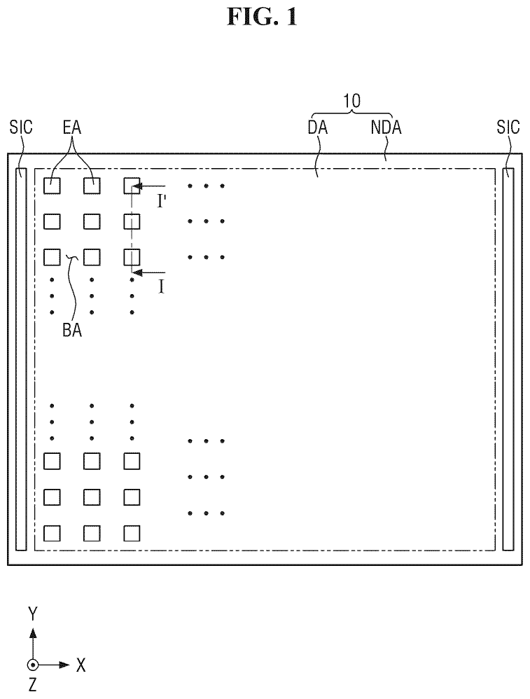

FIG. 1 is a schematic plan view illustrating a display device according to an embodiment.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. As another example, the display device 10 may be applied as a display unit of a television, a laptop, a monitor, a billboard, or an Internet-of-Things (IoT) device. As still another example, the display device 10 may be applied to wearable devices such as a smart watch, a watch phone, a glasses type display, or a head mounted display (HMD).

The display device 10 may have a planar shape similar to a quadrilateral shape. For example, in the display device 10, the corner where the side in the X-axis direction and the side in the Y-axis direction meet may be rounded to have a predetermined or selected curvature or may be right-angled. The planar shape of the display device 10 is not limited to a quadrilateral shape, and may be formed in a shape similar to another polygonal shape, a circular shape, or elliptical shape.

The display device 10 may include a display area DA and a non-display area NDA. The display area DA may include multiple pixels to display an image. Each of the pixels may include an organic light emitting diode (LED) including an organic light emitting layer, a quantum dot LED including a quantum dot light emitting layer, an inorganic LED including an inorganic semiconductor, or a micro LED. In the following, the case where each of the pixels includes an organic light emitting diode will be mainly described, but the disclosure is not limited thereto.

The pixels may be arranged along rows and columns in the display area DA. Each of the pixels may include an emission area EA defined by a pixel defining layer or bank, and may emit light having a predetermined or selected peak wavelength through the emission area EA. The emission area EA may be an area in which light generated from the light emitting element of the display device 10 is emitted to the outside of the display device 10.

The display area DA of the display device 10 may include a light blocking area BA surrounding the emission areas EA. The light blocking area BA may prevent color mixing of lights emitted from the emission areas EA.

The non-display area NDA may be disposed around the display area DA to surround the display area DA, and may not display an image. The non-display area NDA may include a scan driver SIC that supplies a scan signal to the display area DA. The scan driver SIC may be disposed on the left and right sides of the non-display area NDA. The scan driver SIC may generate a scan signal based on a scan control signal. The scan control signal may include a start signal, a clock signal, and a power voltage, but the disclosure is not limited thereto. The scan driver SIC may supply scan signals to scan lines of the display area DA in a set sequence.

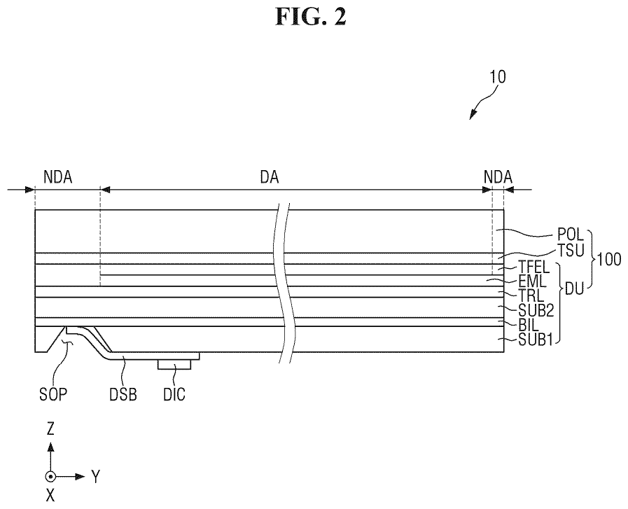

FIG. 2 is a schematic cross-sectional view illustrating a display device according to an embodiment.

Referring to FIG. 2, the display panel 100 may include a display unit DU, a touch sensing unit TSU, and an optical member POL. The display unit DU may include a first substrate SUB1, a barrier insulating layer BIL, a second substrate SUB2, a transistor layer TRL, a light emitting element layer EML, and an encapsulation layer TFEL.

The first substrate SUB1 may support the display device 10. The first substrate SUB1 may be a base substrate or a base part. The first substrate SUB1 may be a flexible substrate which can be bent, folded or rolled. For example, the first substrate SUB1 may include an insulating material such as a polymer resin such as polyimide (PI), but the disclosure is not limited thereto. As another example, the first substrate SUB1 may be a rigid substrate including a glass material.

The barrier insulating layer BIL may be disposed on the first substrate SUB1. The barrier insulating layer BIL may include an inorganic layer capable of preventing permeation of air or moisture. For example, the barrier insulating layer BIL may include at least one of a silicon nitride layer, a silicon oxynitride layer, a silicon oxide layer, a titanium oxide layer, an aluminum oxide layer, and an amorphous silicon layer, but the disclosure is not limited thereto.

The second substrate SUB2 may be disposed on the barrier insulating layer BIL. The second substrate SUB2 may be a base substrate or a base part. The second substrate SUB2 may be a flexible substrate which can be bent, folded or rolled. For example, the second substrate SUB2 may include an insulating material such as a polymer resin such as polyimide (PI), but the disclosure is not limited thereto.

The transistor layer TRL may be disposed on the second substrate SUB2. The transistor layer TRL may include transistors constituting a pixel circuit of pixels. The transistor layer TRL may include scan lines, data lines, and power lines connected to the pixels. Each of the transistors may include a semiconductor region, a source electrode, a drain electrode, and a gate electrode. For example, in case that the scan driver is formed on a side of the non-display area NDA of the display panel 100, the scan driver may include transistors.

The transistor layer TRL may be disposed in the display area DA and the non-display area NDA. Transistors, scan lines, data lines, and power lines of each of the pixels of the transistor layer TRL may be disposed in the display area DA. The transistors of the scan driver SIC may be disposed in the non-display area NDA.

The light emitting element layer EML may be disposed on the transistor layer TRL. The light emitting element layer EML may include light emitting elements in which a pixel electrode, a light emitting layer, and a common electrode are sequentially stacked to emit light, and a pixel defining layer defining pixels. The light emitting elements of the light emitting element layer EML may be disposed in the display area DA.

For example, the light emitting layer may be an organic light emitting layer including an organic material. The light emitting layer may include a hole transporting layer, an organic light emitting layer, and an electron transporting layer. In case that the pixel electrode receives a predetermined or selected voltage through the transistor of the transistor layer TRL and the common electrode receives a cathode voltage, holes move to the organic light emitting layer through the hole transporting layer, and electrons move to the organic light emitting layer through the electron transporting layer, so that the holes and the electrons may combine with each other in the organic light emitting layer to emit light. For example, the pixel electrode may be an anode electrode, and the common electrode may be a cathode electrode, but the disclosure is not limited thereto.

As another example, the light emitting elements may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EML, and may protect the light emitting element layer EML. The encapsulation layer TFEL may include at least one inorganic layer and at least one organic layer for encapsulating the light emitting element layer EML.

The touch sensing unit TSU may be disposed on the encapsulation layer TFEL. The touch sensing unit TSU may include touch electrodes for sensing a user's touch in a capacitive manner, and touch lines for supplying touch driving signals to the touch electrodes. For example, the touch sensing unit TSU may sense the user's touch by using a mutual capacitance method or a self-capacitance method.

The touch electrodes of the touch sensing unit TSU may be disposed in a touch sensor area overlapping the display area DA. The touch lines of the touch sensing unit TSU may be disposed in a touch peripheral area that overlaps the non-display area NDA.

The optical member POL may be disposed on the touch sensing unit TSU. The optical member POL may be attached onto the touch sensing unit TSU by an optically clear adhesive (OCA) film or an optically clear resin (OCR). For example, the optical member POL may include a linear polarizer and a phase retardation film, and the phase retardation film may be a λ/4 plate (quarter-wave plate). The phase retardation film and the linear polarizer plate may be sequentially stacked on the touch sensing unit TSU. The optical member POL may reduce reflected light by external light, thereby preventing color distortion due to external light reflection.

The first substrate SUB1 may include an opening SOP. The opening SOP of the first substrate SUB1 may be formed by etching the bottom surface of the first substrate SUB1 to penetrate the top surface of the first substrate SUB1. For example, the lower width of the opening SOP may be larger than the upper width of the opening SOP. During the manufacturing process of the display device 10, a pad part provided in the barrier insulating layer BIL may be exposed through the opening SOP of the first substrate SUB1. The pad part may be electrically connected to a display driver DIC through a driver substrate DSB inserted into the opening SOP.

The driver substrate DSB may be disposed below the first substrate SUB1. A part of the driver substrate DSB may be inserted into the opening SOP of the first substrate SUB1 and electrically connected to the pad part. The driver substrate DSB may support the display driver DIC. The driver substrate DSB may transmit the signal and voltage of the display driver DIC to the transistor layer TRL. The driver substrate DSB may supply a scan control signal to the scan driver SIC.

The display driver DIC may be mounted on the driver substrate DSB. The display driver DIC may be an integrated circuit (IC). The display driver DIC may convert digital video data into an analog data voltage based on the data control signal received from a timing controller (not shown), and supply the analog data voltage to the data line of the display area DA through the driver substrate DSB. The display driver DIC may supply the power voltage received from a power supply unit (not shown) to the power line of the display area DA through the driver substrate DSB. The display device 10 may include the driver substrate DSB electrically connected to the pad part at the opening SOP of the first substrate SUB1, thereby minimizing the size of the non-display area NDA.

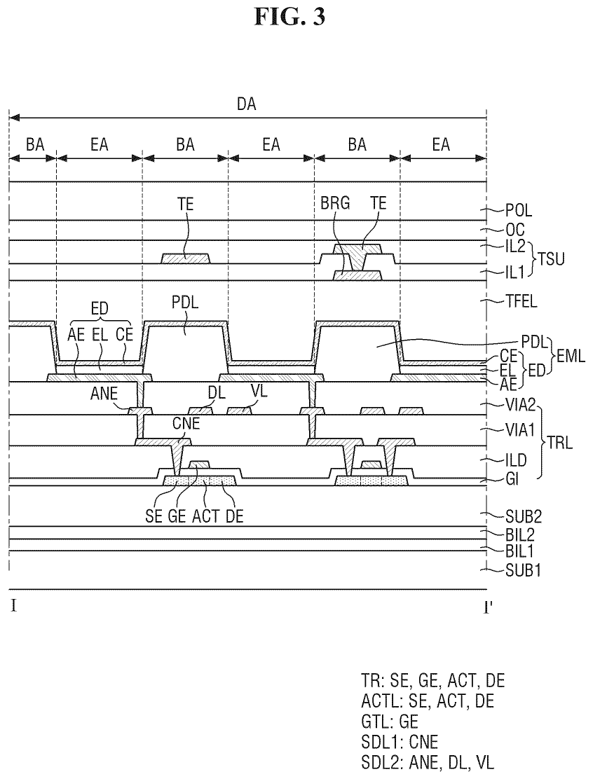

FIG. 3 is a schematic cross-sectional view taken along line I-I′ of FIG. 1.

Referring to FIG. 3, the display area DA of the display device 10 may include emission areas EA. Each of the emission areas EA may be an area in which light generated from the light emitting element ED is emitted to the outside of the display device 10.

The display panel 100 may include the first substrate SUB1, a first barrier insulating layer BIL1, a second barrier insulating layer BIL2, the second substrate SUB2, the transistor layer TRL, the light emitting element layer EML, the encapsulation layer TFEL, the touch sensing unit TSU, a planarization layer OC, and the optical member POL.

The first substrate SUB1 may support the display panel 100. The first substrate SUB1 may be a base substrate or a base part. The first substrate SUB1 may be a flexible substrate which can be bent, folded or rolled. For example, the first substrate SUB1 may include an insulating material such as a polymer resin such as polyimide (PI), but the disclosure is not limited thereto. As another example, the first substrate SUB1 may be a rigid substrate including a glass material.

The first barrier insulating layer BIL1 may be disposed on the first substrate SUB1. The first barrier insulating layer BIL1 may include an inorganic layer capable of preventing permeation of air or moisture. For example, the first barrier insulating layer BIL1 may include at least one of a silicon nitride layer, a silicon oxynitride layer, a silicon oxide layer, a titanium oxide layer, an aluminum oxide layer, and an amorphous silicon layer, but the disclosure is not limited thereto.

The second barrier insulating layer BIL2 may be disposed on the first barrier insulating layer BIL1. The second barrier insulating layer BIL2 may include an inorganic layer capable of preventing permeation of air or moisture. For example, the second barrier insulating layer BIL2 may be formed as a double layer including silicon oxide (SiOx) and amorphous silicon (a-Si). The second barrier insulating layer BIL2 may include amorphous silicon (a-Si) to enhance adhesion between its upper and lower layers, thereby overcoming delamination defects. The second substrate SUB2 may be disposed on the second barrier insulating layer BIL2. The second substrate SUB2 may be a base substrate or a base part. The second substrate SUB2 may be a flexible substrate which can be bent, folded or rolled. For example, the second substrate SUB2 may include an insulating material such as a polymer resin such as polyimide (PI), but the disclosure is not limited thereto.

The transistor layer TRL may be disposed on the second substrate SUB2. The transistor layer TRL may include an active layer ACTL, a gate insulating layer GI, a gate layer GTL, an interlayer insulating layer ILD, a first source metal layer SDL1, a first via layer VIA1, a second source metal layer SDL2, and a second via layer VIA2.

The active layer ACTL may be disposed on the second substrate SUB2. The active layer ACTL may include a semiconductor region ACT, a drain electrode DE, and a source electrode SE of the transistor TR. The semiconductor region ACT may overlap a gate electrode GE, and may be insulated from the gate electrode GE by the gate insulating layer GI. The drain electrode DE and the source electrode SE may be provided by making a material of the semiconductor region ACT conductive. The transistor TR may constitute a pixel circuit of each of the pixels.

The gate insulating layer GI may be disposed on the active layer ACTL. The gate insulating layer GI may insulate the gate electrode GE from the semiconductor region ACT of the transistor TR. The gate insulating layer GI may include a contact hole through which the connection electrode CNE passes.

The gate layer GTL may be disposed on the gate insulating layer GI. The gate layer GTL may include a gate electrode GE of the transistor TR. The gate electrode GE may overlap the semiconductor region ACT with the gate insulating layer GI between the gate electrode GE and the semiconductor region ACT. The gate electrode GE may receive a scan signal from the scan line. For example, the gate layer GTL may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The interlayer insulating layer ILD may be disposed on the gate layer GTL. The interlayer insulating layer ILD may insulate the gate layer GTL from the first source metal layer SDL1. The interlayer insulating layer ILD may include a contact hole through which the connection electrode CNE passes.

The first source metal layer SDL1 may be disposed on the interlayer insulating layer ILD. The first source metal layer SDL1 may include a connection electrode CNE. The connection electrode CNE may be inserted into a contact hole penetrating the interlayer insulating layer ILD and the gate insulating layer GI and connected to the source electrode SE of the transistor TR. The connection electrode CNE may electrically connect the transistor TR to an anode connection electrode ANE. The connection electrode CNE may supply a driving current received from the pixel circuit to the light emitting element ED through the anode connection electrode ANE. For example, the first source metal layer SDL1 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The first via layer VIA1 may be disposed on the first source metal layer SDL1. The first via layer VIA1 may planarize the top portion of the pixel circuit and protect the pixel circuit. The first via layer VIA1 may contain an organic insulating material such as polyimide (PI). The first via layer VIA1 may include a contact hole through which the anode connection electrode ANE passes.

The second source metal layer SDL2 may be disposed on the first source metal layer SDL1. The second source metal layer SDL2 may include the anode connection electrode ANE, a data line DL, and a power line VL. The second source metal layer SDL2 may include the material discussed with respect to the first source metal layer SDL1.

The anode connection electrode ANE may be inserted into a contact hole penetrating the first via layer VIA1 and connected to the connection electrode CNE. The anode connection electrode ANE may electrically connect the connection electrode CNE to a pixel electrode AE of the light emitting element ED. The anode connection electrode ANE may supply a driving current received from the connection electrode CNE to the light emitting element ED.

The data line DL may extend in the Y-axis direction in the display area DA. The data line DL may be electrically connected to the transistor TR. The data line DL may supply a data voltage to the pixel circuit.

The power line VL may extend in the Y-axis direction in the display area DA. The power line VL may be electrically connected to the transistor TR or the light emitting element ED. For example, the power line VL may be a high potential line, a low potential line, an initialization voltage line, a reference voltage line, or a bias voltage line, but is not limited thereto.

The second via layer VIA2 may be disposed on the second source metal layer SDL2. The second via layer VIA2 may planarize the top portion of the transistor layer TRL. The second via layer VIA2 may contain an organic insulating material such as polyimide (PI). The second via layer VIA2 may include a contact hole through which the pixel electrode AE passes.

The light emitting element layer EML may be disposed on the transistor layer TRL. The light emitting element layer EML may include the light emitting element ED and a pixel defining layer PDL.

The light emitting element ED may be disposed in the emission area EA on the second via layer VIA2. The light emitting element ED of each of the pixels may include the pixel electrode AE, a light emitting layer EL, and a common electrode CE. The pixel electrode AE may be disposed on the second via layer VIA2. The pixel electrode AE may overlap one of the emission areas EA defined by the pixel defining layer PDL. For example, the pixel electrode AE may receive a driving current from the pixel circuit through the anode connection electrode ANE and the connection electrode CNE.

The light emitting layer EL may be disposed on the pixel electrode AE. For example, the light emitting layer EL may be an organic light emitting layer made of an organic material, but is not limited thereto. In the case where the light emitting layer EL corresponds to an organic light emitting layer, in case that a predetermined or selected voltage is applied to the pixel electrode AE in the pixel circuit of the pixel, and the common electrode CE receives a common voltage or a cathode voltage, holes may move to the light emitting layer EL through the hole transporting layer, electrons may move to the light emitting layer EL through the electron transporting layer, and the holes and the electrons may combine with each other in the light emitting layer EL to emit light.

The common electrode CE may be arranged on the light emitting layer EL. For example, the common electrode CE may be made in the form of an electrode common to all of the pixels rather than specific to each of the pixels. The common electrode CE may be disposed on the light emitting layer EL in multiple emission areas, and may be disposed on the pixel defining layer PDL in an area except the emission areas.

The pixel defining layer PDL may be disposed in the light blocking area BA on the second via layer VIA2. The pixel defining layer PDL may define emission areas EA or opening areas. The pixel defining layer PDL may separate and insulate the pixel electrodes AE of the pixels.

The encapsulation layer TFEL may be disposed on the common electrode CE to cover the light emitting elements ED. The encapsulation layer TFEL may include at least one inorganic layer to prevent oxygen or moisture from permeating into the light emitting elements ED. The encapsulation layer TFEL may include at least one organic layer to protect the light emitting elements ED from foreign matters such as dust.

The touch sensing unit TSU may be disposed on the encapsulation layer TFEL. The touch sensing unit TSU may include a bridge electrode BRG, a first insulating layer IL1, touch electrodes TE, and a second insulating layer IL2.

The bridge electrode BRG may be disposed on the encapsulation layer TFEL. The bridge electrode BRG may be disposed on a different layer from the touch electrodes TE and may electrically connect the touch electrodes TE that are adjacent to each other.

The first insulating layer IL1 may be disposed on the bridge electrode BRG. The first insulating layer IL1 may have an insulating and optical function. For example, the first insulating layer IL1 may be an inorganic layer containing at least one of a silicon nitride layer, a silicon oxynitride layer, a silicon oxide layer, a titanium oxide layer, and an aluminum oxide layer. As another example, the first insulating layer IL1 may include an organic layer.

The touch electrode TE may be disposed in the light blocking area BA on the first insulating layer IL1. The touch electrode TE may sense the user's touch in a capacitive manner. For example, the touch sensing unit TSU may sense the user's touch using a mutual capacitance method formed between the touch electrodes TE, or a self-capacitance method formed on each of the touch electrodes TE. The touch electrode TE may be formed of a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

The second insulating layer IL2 may be disposed on the touch electrode TE. The second insulating layer IL2 may have an insulating and optical function. The second insulating layer IL2 may be made of the material illustrated in the first insulating layer IL1.

The planarization layer OC may be disposed on the touch sensing unit TSU to planarize the top portion of the touch sensing unit TSU. For example, the planarization layer OC may include an organic insulating material.

The optical member POL may be disposed on the planarization layer OC. The optical member POL may be attached onto the touch sensing unit TSU by an optically clear adhesive (OCA) film or an optically clear resin (OCR). For example, the optical member POL may include a linear polarizer and a phase retardation film, and the phase retardation film may be a λ/4 plate (quarter-wave plate). The phase retardation film and the linear polarizer plate may be sequentially stacked on the touch sensing unit TSU. The optical member POL may reduce reflected light by external light, thereby preventing color distortion due to external light reflection.

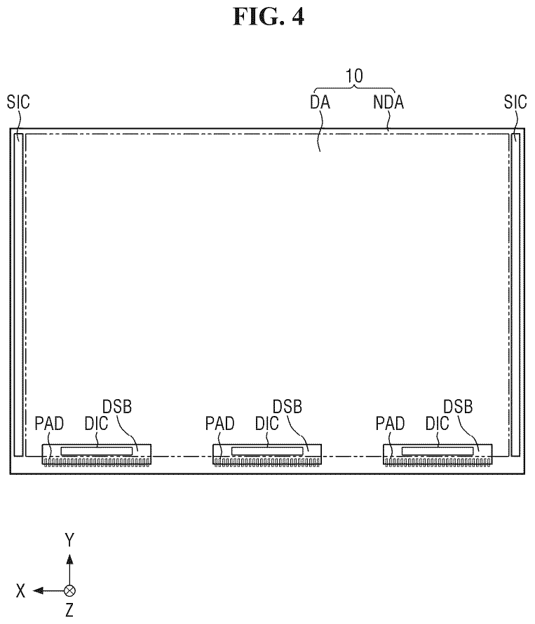

FIG. 4 is a schematic bottom view illustrating a display device according to an embodiment.

Referring to FIG. 4, the driver substrate DSB may be disposed below the first substrate SUB1. The driver substrate DSB may be disposed at the edge of the bottom surface of the display panel 100. The driver substrate DSB may be attached to the bottom surface of a pad part PAD through an adhesive member. A lead line of the driver substrate DSB may be electrically connected to the pad part PAD through a contact portion. The pad part PAD may be disposed in the non-display area NDA, but is not limited thereto.

The display driver DIC may be mounted on the driver substrate DSB. The display driver DIC may be an integrated circuit (IC). The display driver DIC may convert digital video data into an analog data voltage based on the data control signal received from a timing controller (not shown), and supply the analog data voltage to the data line DL of the display area DA through the driver substrate DSB. The display driver DIC may supply the power voltage received from a power supply unit (not shown) to the power line VL of the display area DA through the driver substrate DSB. The display driver DIC may supply a scan control signal to the scan driver SIC through the driver substrate DSB. The display device 10 may include the pad part PAD disposed above the first substrate SUB1, and the driver substrate DSB and the display driver DIC disposed below the first substrate SUB1, thereby minimizing the size of the non-display area NDA.

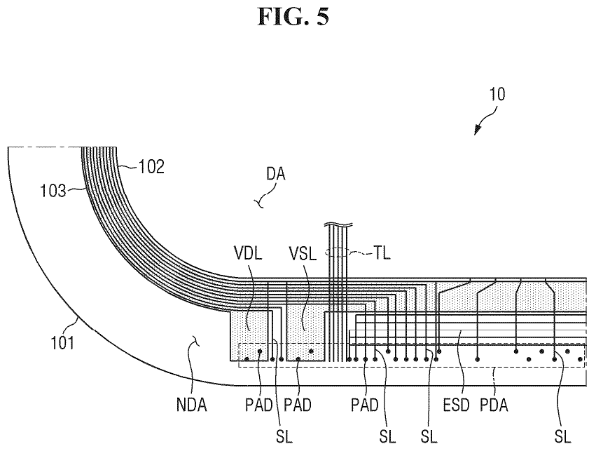

FIG. 5 is a schematic plan view illustrating a part of a non-display area of a display device according to an embodiment.

Referring to FIG. 5, the non-display area NDA may include a signal line SL, a high potential line VDL, a low potential line VSL, and a touch line TL. The signal line SL, the high potential line VDL, the low potential line VSL, and the touch line TL may extend from a pad area PDA to the display area DA. The signal line SL may be electrically connected to the data line DL to supply a data voltage, and may be electrically connected to the scan driver SIC to supply a scan control signal. The high potential line VDL may be electrically connected to the power line VL of the display area DA to supply a high potential voltage to the pixel circuit. The low potential line VSL may be electrically connected to the common electrode CE of the light emitting element ED to supply a low potential voltage. The touch line TL may be electrically connected to the touch electrode TE of the touch sensing unit TSU to supply a touch driving signal. The signal line SL, the high potential line VDL, the low potential line VSL, and the touch line TL may receive a signal or a voltage from the driver substrate DSB disposed below the display panel 100 through the pad part PAD.

The non-display area NDA may further include an anti-static circuit ESD. The anti-static circuit ESD may overlap the signal line SL and be electrically connected to the signal line SL. Accordingly, the anti-static circuit ESD may prevent static electricity introduced from the outside from entering the display area DA through the signal line SL.

A solid line 101 in FIG. 5 indicates a boundary of the display panel 100 corresponding to a corner of the display panel 100. A solid line 102 in FIG. 5 is an imaginary line indicating the boundary between the non-display area NDA and the display area DA of the display panel 100. A solid line 103 in FIG. 5 indicates a boundary where the encapsulation layer TFEL of the display panel 100 is disposed. Accordingly, the signal line SL, the high potential line VDL, and the low potential line VSL may extend to the pad part PAD along the non-display area NDA, inside the boundary where the encapsulation layer TFEL is disposed. The signal line SL, the high potential line VDL, and the low potential line VSL may not be disposed at the outer edge beyond the encapsulation layer TFEL.

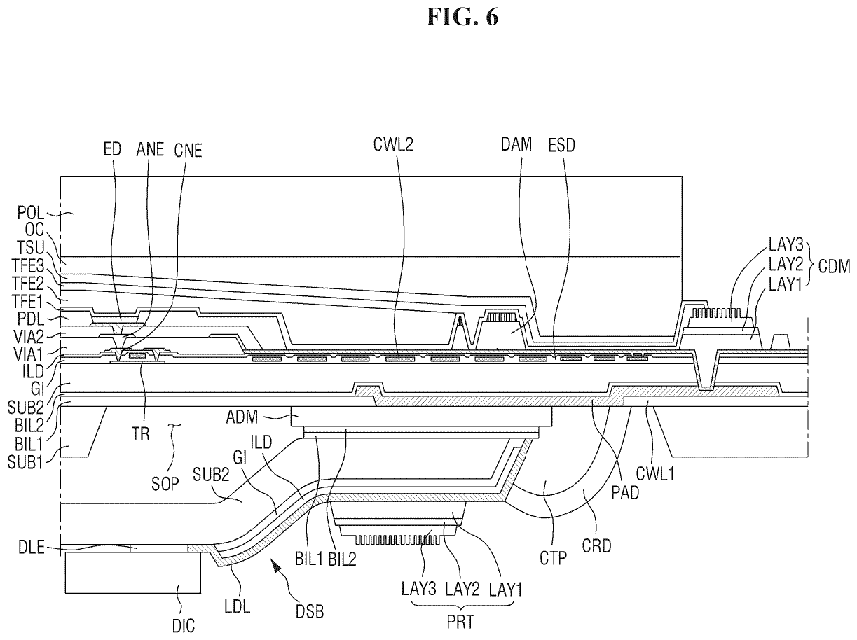

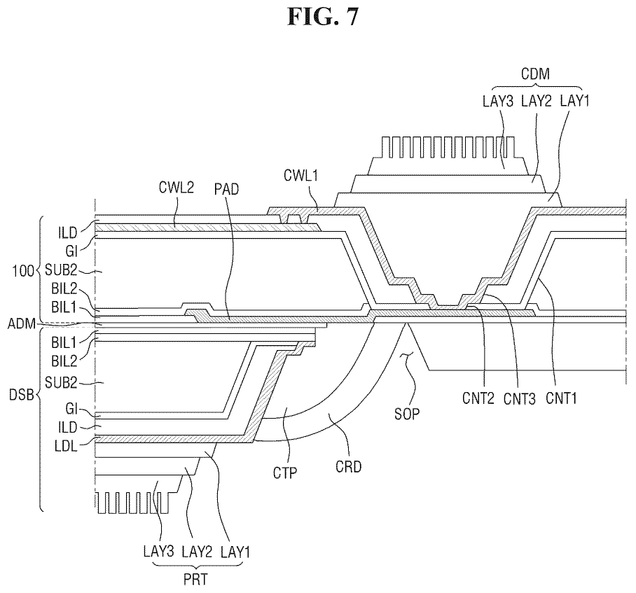

FIG. 6 is a schematic cross-sectional view illustrating a part of a display device according to an embodiment. FIG. 7 is a schematic cross-sectional view illustrating a driver substrate of a display device according to an embodiment. Hereinafter, the same configurations as the above-described configurations will be only briefly described, or a description thereof will be omitted.

Referring to FIGS. 6 and 7, the display device 10 may include the first substrate SUB1, the first barrier insulating layer BIL1, the pad part PAD, the second barrier insulating layer BIL2, the second substrate SUB2, the transistor layer TRL, the light emitting element layer EML, the encapsulation layer TFEL, a dam DAM, the anti-static circuit ESD, a crack prevention portion CDM, the touch sensing unit TSU, the planarization layer OC, the optical member POL, the driver substrate DSB, and the display driver DIC.

The pad part PAD may be disposed on the first barrier insulating layer BIL1 and inserted into a contact hole provided in the first barrier insulating layer BIL1. During the manufacturing process of the display device 10, the pad part PAD may be exposed through the opening SOP of the first substrate SUB1. The pad part PAD may electrically connect the driver substrate DSB to a first connection line CWL1. The pad part PAD may be electrically connected to a lead line LDL of the driver substrate DSB through a contact portion CTP. The pad part PAD may be formed of a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The second barrier insulating layer BIL2 may be disposed on the pad part PAD. The second barrier insulating layer BIL2 may be patterned to expose the top surface of the pad part PAD.

The second substrate SUB2 may include the first contact hole CNT1. The first contact hole CNT1 may be etched from the top surface of the second substrate SUB2 to penetrate the bottom surface of the second substrate SUB2. The upper area of the first contact hole CNT1 may be larger than the lower area of the first contact hole CNT1. During the process of forming the first contact hole CNT1, the top surface of the pad part PAD may be exposed.

The gate insulating layer GI may be disposed on the second substrate SUB2. The gate insulating layer GI may be inserted into the first contact hole CNT1 of the second substrate SUB2 and may include a second contact hole CNT2 overlapping the first contact hole CNT1. A part of the gate insulating layer GI may cover a part of the top surface of the pad part PAD exposed through the first contact hole CNT1. The area of the second contact hole CNT2 in plan view may be smaller than the area of the first contact hole CNT1 in plan view.

The interlayer insulating layer ILD may be disposed on the gate insulating layer GI. The interlayer insulating layer ILD may be inserted into the first contact hole CNT1 of the second substrate SUB2 and may include a third contact hole CNT3 overlapping the first and second contact holes CNT1 and CNT2. A part of the top surface of the gate insulating layer GI adjacent to the second contact hole CNT2 may be exposed through the third contact hole CNT3. In plan view, the area of the third contact hole CNT3 may be larger than the area of the second contact hole CNT2 and smaller than the area of the first contact hole CNT1.

The first connection line CWL1 may be disposed on the interlayer insulating layer ILD. The first connection line CWL1 may be formed in the same process and contain the same material as the first source metal layer SDL1 of the display area DA. An end of the first connection line CWL1 may be sequentially inserted into the first contact hole CNT1, the third contact hole CNT3, and the second contact hole CNT2 to be brought into contact with the top surface of the pad part PAD. The other end of the first connection line CWL1 may penetrate the interlayer insulating layer ILD to be brought into contact with a second connection line CWL2. The first connection line CWL1 may electrically connect the pad part PAD to the second connection line CWL2. The first connection line CWL1 may supply a data voltage or power voltage received from the pad part PAD to the second connection line CWL2.

The second connection line CWL2 may be disposed on the gate insulating layer GI. The second connection line CWL2 may be formed in the same process and contain the same material as the gate layer GTL of the display area DA. The second connection line CWL2 may supply a data voltage received from the first connection line CWL1 to the data line DL, and supply a power voltage received from the first connection line CWL1 to the power line VL. For example, the second connection line CWL2 may correspond to the signal line SL of FIG. 5, or may be electrically connected to the signal line SL.

The encapsulation layer TFEL may include first to third encapsulation layers TFE1, TFE2, and TFE3.

The first encapsulation layer TFE1 may be disposed on the light emitting element layer EML. The first encapsulation layer TFE1 may include an inorganic material to prevent oxygen or moisture from permeating into the light emitting element layer EML. The first encapsulation layer TFE1 may extend beyond the display area DA and the dam DAM to the crack prevention portion CDM. For example, the first encapsulation layer TFE1 may include at least one of a silicon nitride layer, a silicon oxynitride layer, a silicon oxide layer, a titanium oxide layer, an aluminum oxide layer, and an amorphous silicon layer, but the disclosure is not limited thereto.

The second encapsulation layer TFE2 may be disposed on the first encapsulation layer TFE1. The second encapsulation layer TFE2 may include an organic material to protect the light emitting element layer EML from foreign substances such as dust. The second encapsulation layer TFE2 may extend beyond the display area DA to the dam DAM. The second encapsulation layer TFE2 may be formed by filling an area surrounded by the dam DAM. For example, the second encapsulation layer TFE2 may include an organic layer such as acryl resin, epoxy resin, phenolic resin, polyamide resin, polyimide resin and the like. The second encapsulation layer TFE2 may be formed by curing a monomer or applying a polymer.

The third encapsulation layer TFE3 may be disposed on the second encapsulation layer TFE2. The third encapsulation layer TFE3 may include an inorganic material to prevent oxygen or moisture from permeating into the light emitting element layer EML. The third encapsulation layer TFE3 may extend beyond the display area DA and the dam DAM to the crack prevention portion CDM. The third encapsulation layer TFE3 may be disposed on the second encapsulation layer TFE2 inside the dam DAM, and may be disposed on the first encapsulation layer TFE1 inside the crack prevention portion CDM. For example, the third encapsulation layer TFE3 may be made of the material discussed with respect to the first encapsulation layer TFE1.

The dam DAM may surround the display area DA. The dam DAM may be formed in the same process and contain the same material as the pixel defining layer PDL. The dam DAM may have a predetermined or selected height such that the second encapsulation layer TFE2 containing an organic material does not extend beyond the dam DAM.

The anti-static circuit ESD may be disposed between the display area DA and the crack prevention portion CDM. The anti-static circuit ESD may include at least one transistor. The anti-static circuit ESD may be electrically connected to the second connection line CWL2. Accordingly, the anti-static circuit ESD may prevent static electricity introduced from the outside from entering the display area DA through the second connection line CWL2.

The crack prevention portion CDM may surround the dam DAM. The crack prevention portion CDM may be disposed at the outermost portion of the display panel 100 to prevent cracks in the display panel 100. The first and third encapsulation layers TFE1 and TFE3 and the planarization layer OC may be formed in an area surrounded by the crack prevention portion CDM.

The crack prevention portion CDM may include first to third layers LAY1, LAY2, and LAY3. The first layer LAY1 of the crack prevention portion CDM may cover the top surface of the first connection line CWL1 inserted into the first to third contact holes CNT1, CNT2, and CNT3. The first layer LAY1 may fill the stepped portion caused by the first contact hole CNT1 of the second substrate SUB2. The first layer LAY1 may be formed in the same process and contain the same material as the first via layer VIA1.

The second layer LAY2 of the crack prevention portion CDM may be disposed on the first layer LAY1. The second layer LAY2 may be formed in the same process and contain the same material as the second via layer VIA2.

The third layer LAY3 of the crack prevention portion CDM may be disposed on the second layer LAY2. The third layer LAY3 may be formed in the same process and contain the same material as the pixel defining layer PDL.

The driver substrate DSB may be disposed below the first substrate SUB1. A side of the driver substrate DSB may be inserted into the opening SOP of the first substrate SUB1 and electrically connected to the pad part PAD. The driver substrate DSB may be attached to the bottom surfaces of the pad part PAD and the first barrier insulating layer BIL1 through an adhesive member ADM. The driver substrate DSB may be manufactured to include some layers of the display panel 100 during the manufacturing process of the display panel 100. After being separated from the display panel 100, the driver substrate DSB may be turned upside down and inserted into the opening SOP of the first substrate SUB1.

The driver substrate DSB may include the first barrier insulating layer BIL1, the second barrier insulating layer BIL2, the second substrate SUB2, the gate insulating layer GI, the interlayer insulating layer ILD, the lead line LDL, and a protective part PRT.

The first barrier insulating layer BIL1 may be attached to the bottom surfaces of the pad part PAD and the first barrier insulating layer BIL1 of the display panel 100 through the adhesive member ADM. The first barrier insulating layers BIL1 of the display panel 100 and the driver substrate DSB may contain the same material and be formed in the same process.

The second barrier insulating layer BIL2 may be disposed on the first barrier insulating layer BIL1. The second barrier insulating layers BIL2 of the display panel 100 and the driver substrate DSB may contain the same material and be formed in the same process.

The second substrate SUB2 may be disposed on the second barrier insulating layer BIL2. The second substrate SUB2 may be a base substrate or a base part of the driver substrate DSB. The second substrate SUB2 may have a side surface tapered from the top surface. The inclination angle of the side surface of the second substrate SUB2 may be 80 degrees or less with respect to the top surface of the second substrate SUB2. For example, the angle between the top surface of the second substrate SUB2 facing the second barrier insulating layer BIL2 and the side surface of the second substrate SUB2 facing the gate insulating layer GI may be 45 degrees to 80 degrees, but is not limited thereto. The second substrates SUB2 of the display panel 100 and the driver substrate DSB may contain the same material and be formed in the same process.

The gate insulating layer GI may be disposed on the second substrate SUB2. The gate insulating layer GI may cover the bottom and side surfaces of the second substrate SUB2. The gate insulating layers GI of the display panel 100 and the driver substrate DSB may contain the same material and be formed in the same process.

The interlayer insulating layer ILD may be disposed on the gate insulating layer GI. The interlayer insulating layers ILD of the display panel 100 and the driver substrate DSB may contain the same material and be formed in the same process.

The lead line LDL may be disposed on the interlayer insulating layer ILD. The lead line LDL may extend along the bottom and side surfaces of the second substrate SUB2. An end of the lead line LDL may be connected to a bump electrode DLE of the display driver DIC, and the other end of the lead line LDL may be connected to the contact portion CTP. The lead line LDL may electrically connect the bump electrode DLE of the display driver DIC to the pad part PAD of the display panel 100. The lead line LDL may be formed in the same process and contain the same material as the first source metal layer SDL1 of the display panel 100. For example, the lead line LDL may have a stacked structure of titanium/aluminum/titanium (Ti/Al/Ti), but is not limited thereto.

The protective part PRT may be disposed on the lead line LDL and the interlayer insulating layer ILD. The protective part PRT may be disposed below the driver substrate DSB to protect the driver substrate DSB. The protective part PRT may prevent permeation of moisture and external air. The protective part PRT may protect the lead line LDL that is not covered by the contact portion CTP and a cover layer CRD. The protective part PRT may be formed in the same process and contain the same material as the crack prevention portion CDM of the display panel 100.

The protective part PRT may include first to third layers LAY1, LAY2, and LAY3. The first layer LAY1 of the protective part PRT may be disposed on the lead line LDL and the interlayer insulating layer ILD. The first layer LAY1 of each of the crack prevention portion CDM and the protective part PRT may be formed in the same process and contain the same material as the first via layer VIA1.

The second layer LAY2 of the protective part PRT may be disposed on the first layer LAY1. The second layer LAY2 of each of the crack prevention portion CDM and the protective part PRT may be formed in the same process and contain the same material as the second via layer VIA2.

The third layer LAY3 of the protective part PRT may be disposed on the second layer LAY2. The third layer LAY3 of each of the crack prevention portion CDM and the protective part PRT may be formed in the same process and contain the same material as the pixel defining layer PDL.

The display driver DIC may be mounted on the driver substrate DSB. The bump electrode DLE of the display driver DIC may be disposed on the bottom surface of the second substrate SUB2. The bump electrode DLE of the display driver DIC may be electrically connected to the pad part PAD through the lead line LDL and the contact portion CTP. The display driver DIC may be an integrated circuit (IC). The display driver DIC may convert digital video data into an analog data voltage based on the data control signal received from a timing controller (not shown), and supply the analog data voltage to the data line DL of the display area DA through the driver substrate DSB and the pad part PAD. The display driver DIC may supply the power voltage received from a power supply unit (not shown) to the power line VL of the display area DA through the driver substrate DSB and the pad part PAD. The display device 10 may include the pad part PAD and the first and second connection lines CWL1 and CWL2 disposed above the first substrate SUB1, and the driver substrate DSB and the display driver DIC disposed below the first substrate SUB1, thereby minimizing the size of the non-display area NDA.

The contact portion CTP may cover the lead line LDL exposed on the side surface of the driver substrate DSB. The contact portion CTP may be in contact with the lead line LDL disposed on the tapered side surface of the second substrate SUB2. The contact portion CTP may electrically connect the lead line LDL to the pad part PAD and may protect the lead line LDL.

For example, the contact portion CTP may be formed by low temperature sintering of conductive ink containing nanoparticles and polymers. The nanoparticles may include nanoscale metal particles such as silver (Ag), copper (Cu), aluminum (Al), or chromium (Cr), and the polymer may include an acrylic resin or an epoxy resin, but they are not limited thereto. The conductive ink may contain a polymer as a binder that connects metal particles, and the nanoparticles may agglomerate by adhering to each other through a sintering process. The contact portion CTP may have conductivity by including sintered nanoparticles.

As another example, the contact portion CTP may be formed by low temperature sintering of metal organic decomposition ink (MOD ink). The metal organic decomposition ink may contain liquid metal organic decomposition substances smaller than nanoparticles, and the liquid metal organic decomposition substances may be converted into metal substances through a sintering process. Accordingly, the contact portion CTP may have conductivity.

The contact portion CTP may be formed by printing conductive ink or metal paste in the opening SOP of the first substrate SUB1 using a silicon pad, and sintering using an optical pulse (intense pulsed light (IPL)) or a laser. The specific resistance of the contact portion CTP may decrease as metal particles adhere and agglomerate together due to the heat generated by the optical pulse or laser during the sintering process.

The cover layer CRD may be disposed on the contact portion CTP to protect the contact portion CTP. The cover layer CRD may include an organic layer such as acryl resin, epoxy resin, phenolic resin, polyamide resin, polyimide resin and the like. The cover layer CRD may be formed by curing a monomer or applying a polymer.

The display device 10 may include the driver substrate DSB manufactured simultaneously with the display panel 100, thereby omitting a separate flexible film or flexible printed circuit board and reducing manufacturing cost. In the display device 10, the lead line LDL may be electrically connected to the pad part PAD through the contact portion CTP that uses metal paste, thereby simplifying the manufacturing process without using ultrasonic bonding or thermocompression bonding, and reducing manufacturing time and manufacturing cost.

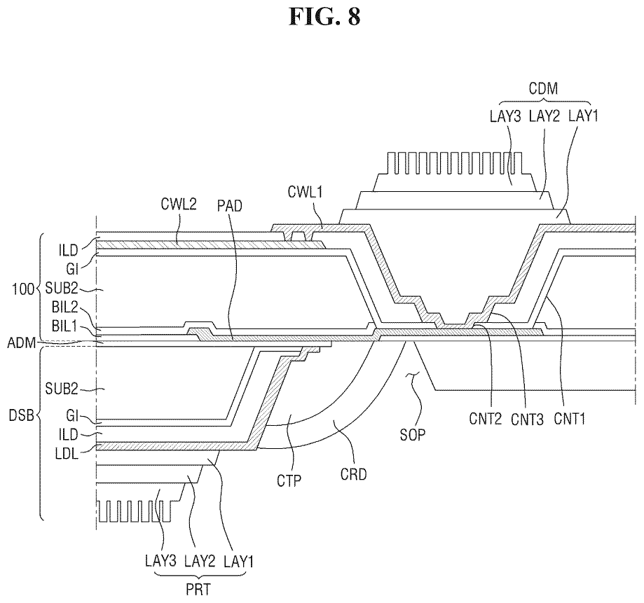

FIG. 8 is a schematic cross-sectional view illustrating a driver substrate of a display device according to another embodiment. The driver substrate of FIG. 8 may omit the first and second barrier insulating layers BIL1 and BIL2 from the driver substrate of FIG. 7. The same configuration as the above-described configuration will be only briefly described or omitted.

Referring to FIG. 8, the driver substrate DSB may include the second substrate SUB2, the gate insulating layer GI, the interlayer insulating layer ILD, the lead line LDL, and the protective part PRT.

The second substrate SUB2 may be directly attached to the adhesive member ADM. The second substrate SUB2 may be attached to the bottom surfaces of the pad part PAD and the first barrier insulating layer BIL1 through the adhesive member ADM. The second substrate SUB2 may be a base substrate or a base part of the driver substrate DSB. The second substrate SUB2 may have a side surface tapered from the top surface.

The gate insulating layer GI may be disposed on the second substrate SUB2. The gate insulating layer GI may cover the bottom and side surfaces of the second substrate SUB2. The interlayer insulating layer ILD may be disposed on the gate insulating layer GI.

The lead line LDL may be disposed on the interlayer insulating layer ILD. The lead line LDL may extend along the bottom and side surfaces of the second substrate SUB2. The lead line LDL may electrically connect the bump electrode DLE of the display driver DIC to the pad part PAD of the display panel 100. The lead line LDL may be formed in the same process and contain the same material as the first source metal layer SDL1 of the display panel 100. For example, the lead line LDL may have e a stacked structure of titanium/aluminum/titanium (Ti/Al/Ti), but is not limited thereto.

The protective part PRT may be disposed on the lead line LDL and the interlayer insulating layer ILD. The protective part PRT may be disposed below the driver substrate DSB to protect the driver substrate DSB.

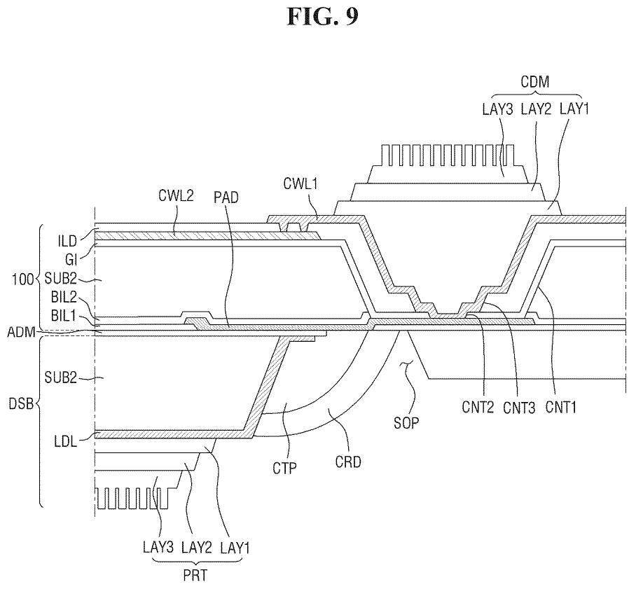

FIG. 9 is a schematic cross-sectional view illustrating a driver substrate of a display device according to still another embodiment. The driver substrate of FIG. 9 may omit the gate insulating layer GI and the interlayer insulating layer ILD from the driver substrate of FIG. 7.

The same configuration as the above-described configuration will be only briefly described or omitted.

Referring to FIG. 9, the driver substrate DSB may include the second substrate SUB2, the lead line LDL, and the protective part PRT.

The first barrier insulating layer BIL1 may be attached to the bottom surfaces of the pad part PAD and the first barrier insulating layer BIL1 of the display panel 100 through the adhesive member ADM. The second barrier insulating layer BIL2 may be disposed on the first barrier insulating layer BIL1.

The second substrate SUB2 may be disposed on the second barrier insulating layer BIL2. The second substrate SUB2 may be a base substrate or a base part of the driver substrate DSB. The second substrate SUB2 may have a side surface tapered from the top surface.

The lead line LDL may be disposed on the second substrate SUB2. The lead line LDL may extend along the bottom and side surfaces of the second substrate SUB2. The lead line LDL may electrically connect the bump electrode DLE of the display driver DIC to the pad part PAD of the display panel 100. The lead line LDL may be formed in the same process and contain the same material as the first source metal layer SDL1 of the display panel 100. For example, the lead line LDL may have a stacked structure of titanium/aluminum/titanium (Ti/Al/Ti), but is not limited thereto.

The protective part PRT may be disposed on the lead line LDL and the second substrate SUB2. The protective part PRT may be disposed below the driver substrate DSB to protect the driver substrate DSB.

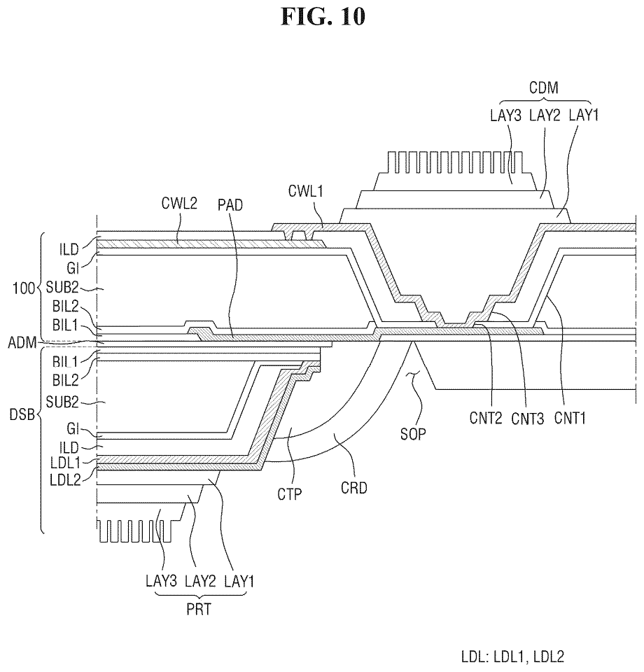

FIG. 10 is a schematic cross-sectional view illustrating a driver substrate of a display device according to still another embodiment. The driver substrate of FIG. 10 further includes a first line layer LDL1 and a second line layer LDL2 compared to the driver substrate of FIG. 7. The same configuration as the above-described configuration will be only briefly described or omitted.

Referring to FIG. 10, the driver substrate DSB may include the first barrier insulating layer BIL1, the second barrier insulating layer BIL2, the second substrate SUB2, the gate insulating layer GI, the interlayer insulating layer ILD, the lead line LDL, and the protective part PRT.

The first barrier insulating layer BIL1 may be attached to the bottom surfaces of the pad part PAD and the first barrier insulating layer BIL1 of the display panel 100 through the adhesive member ADM. The second barrier insulating layer BIL2 may be disposed on the first barrier insulating layer BIL1.

The second substrate SUB2 may be disposed on the second barrier insulating layer BIL2. The second substrate SUB2 may be a base substrate or a base part of the driver substrate DSB. The second substrate SUB2 may have a side surface tapered from the top surface.

The gate insulating layer GI may be disposed on the second substrate SUB2. The gate insulating layer GI may cover the bottom and side surfaces of the second substrate SUB2. The interlayer insulating layer ILD may be disposed on the gate insulating layer GI.

The lead line LDL may be disposed on the interlayer insulating layer ILD. The lead line LDL may extend along the bottom and side surfaces of the second substrate SUB2. The lead line LDL may electrically connect the bump electrode DLE of the display driver DIC to the pad part PAD of the display panel 100. The lead line LDL may include a first line layer LDL1 and the second line layer LDL2.

The first line layer LDL1 may be disposed on the interlayer insulating layer ILD. The first line layer LDL1 may be formed in the same process and contain the same material as the first source metal layer SDL1 of the display panel 100.

The second line layer LDL2 may be disposed on the first line layer LDL1. For example, the second line layer LDL2 may be formed in the same process and contain the same material as the second source metal layer SDL2 of the display panel 100. As another example, the second line layer LDL2 may be formed in the same process and contain the same material as a metal layer on the second source metal layer SDL2. As still another example, the second line layer LDL2 may be formed in the same process and contain the same material as the pixel electrode AE of the display panel 100.

The protective part PRT may be disposed on the second line layer LDL2 and the interlayer insulating layer ILD. The protective part PRT may be disposed below the driver substrate DSB to protect the driver substrate DSB.

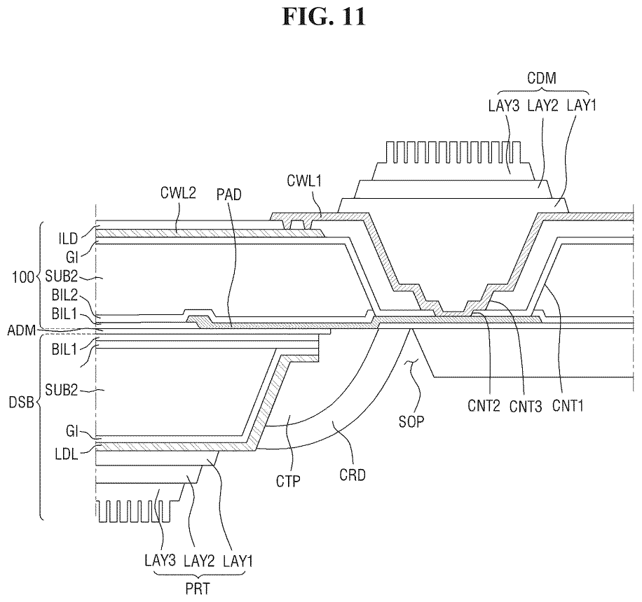

FIG. 11 is a schematic cross-sectional view illustrating a driver substrate of a display device according to still another embodiment. The driver substrate of FIG. 11 differs from the driver substrate of FIG. 7 in that the interlayer insulating layer ILD may be omitted and the metal layer of the lead line LDL may be different. The same configuration as the above-described configuration will be only briefly described or omitted.

Referring to FIG. 11, the driver substrate DSB may include the first barrier insulating layer BIL1, the second substrate SUB2, the gate insulating layer GI, the lead line LDL, and the protective part PRT.

The first barrier insulating layer BIL1 may be attached to the bottom surfaces of the pad part PAD and the first barrier insulating layer BIL1 of the display panel 100 through the adhesive member ADM. The second barrier insulating layer BIL2 may be disposed on the first barrier insulating layer BIL1.

The second substrate SUB2 may be disposed on the second barrier insulating layer BIL2. The second substrate SUB2 may be a base substrate or a base part of the driver substrate DSB. The second substrate SUB2 may have a side surface tapered from the top surface.

The gate insulating layer GI may be disposed on the second substrate SUB2. The gate insulating layer GI may cover the bottom and side surfaces of the second substrate SUB2.

The lead line LDL may be disposed on the gate insulating layer GI. The lead line LDL may extend along the bottom and side surfaces of the second substrate SUB2. The lead line LDL may electrically connect the bump electrode DLE of the display driver DIC to the pad part PAD of the display panel 100. The lead line LDL may be formed in the same process and contain the same material as the gate layer GTL of the display panel 100.

The protective part PRT may be disposed on the lead line LDL and the gate insulating layer GI. The protective part PRT may be disposed below the driver substrate DSB to protect the driver substrate DSB.

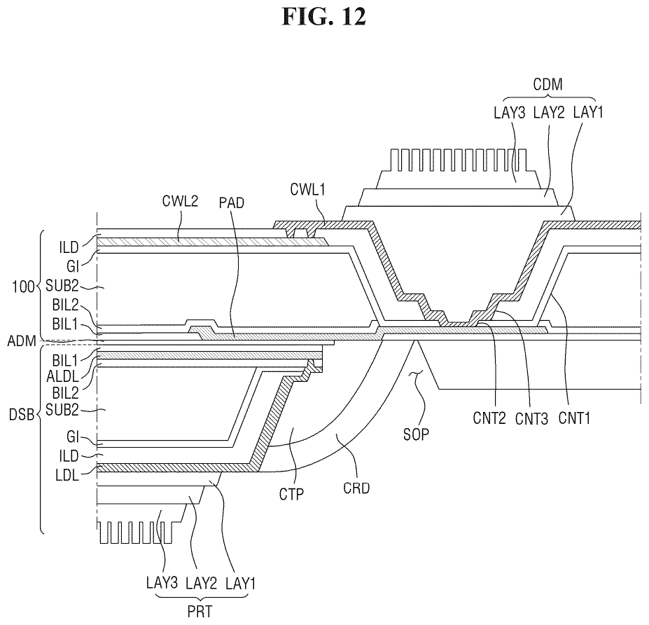

FIG. 12 is a schematic cross-sectional view illustrating a driver substrate of a display device according to still another embodiment. The driver substrate of FIG. 12 may further include an auxiliary line ALDL compared to the driver substrate of FIG. 7. The same configuration as the above-described configuration will be only briefly described or omitted.

Referring to FIG. 12, the driver substrate DSB may include the first barrier insulating layer BIL1, the auxiliary line ALDL, the second barrier insulating layer BIL2, the second substrate SUB2, the gate insulating layer GI, the interlayer insulating layer ILD, the lead line LDL, and the protective part PRT.

The first barrier insulating layer BIL1 may be attached to the bottom surfaces of the pad part PAD and the first barrier insulating layer BIL1 of the display panel 100 through the adhesive member ADM.

The auxiliary line ALDL may be disposed on the first barrier insulating layer BIL1. The auxiliary line ALDL may extend in a layer between the first and second barrier insulating layers BIL1 and BIL2. The auxiliary line ALDL may be electrically connected to the lead line LDL, and the side surface of the auxiliary line ALDL may be in contact with the contact portion CTP. The driver substrate DSB may further include the auxiliary line ALDL, thereby maximizing contact efficiency between the lead line LDL and the contact portion CTP. The auxiliary line ALDL may be formed in the same process and contain the same material as the pad part PAD of the display panel 100.

The second barrier insulating layer BIL2 may be disposed on the auxiliary line ALDL.

The second substrate SUB2 may be disposed on the second barrier insulating layer BIL2. The second substrate SUB2 may be a base substrate or a base part of the driver substrate DSB. The second substrate SUB2 may have a side surface tapered from the top surface.

The gate insulating layer GI may be disposed on the second substrate SUB2. The gate insulating layer GI may cover the bottom and side surfaces of the second substrate SUB2. The interlayer insulating layer ILD may be disposed on the gate insulating layer GI.

The lead line LDL may be disposed on the interlayer insulating layer ILD. The lead line LDL may extend along the bottom and side surfaces of the second substrate SUB2. The lead line LDL may be inserted into a contact hole provided in the second barrier insulating layer BIL2 to be brought into contact with the auxiliary line ALDL. The lead line LDL may electrically connect the bump electrode DLE of the display driver DIC to the pad part PAD of the display panel 100. The lead line LDL may be formed in the same process and contain the same material as the first source metal layer SDL1 of the display panel 100. For example, the lead line LDL may have a stacked structure of titanium/aluminum/titanium (Ti/Al/Ti), but is not limited thereto.

The protective part PRT may be disposed on the lead line LDL and the interlayer insulating layer ILD. The protective part PRT may be disposed below the driver substrate DSB to protect the driver substrate DSB.

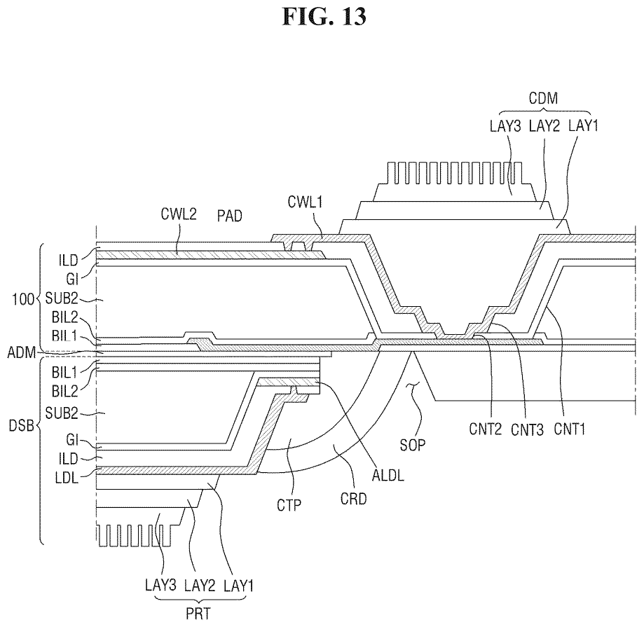

FIG. 13 is a schematic cross-sectional view illustrating a driver substrate of a display device according to still another embodiment. The driver substrate of FIG. 13 differs from the driver substrate of FIG. 7 in that it may have a different configuration of the lead line LDL and may further include the auxiliary line ALDL. The same configuration as the above-described configuration will be only briefly described or omitted.

Referring to FIG. 13, the driver substrate DSB may include the first and second barrier insulating layers BIL1 and BIL2, the second substrate SUB2, the gate insulating layer GI, the auxiliary line ALDL, the interlayer insulating layer ILD, the lead line LDL, and the protective part PRT.

The first barrier insulating layer BIL1 may be attached to the bottom surfaces of the pad part PAD and the first barrier insulating layer BIL1 of the display panel 100 through the adhesive member ADM. The second barrier insulating layer BIL2 may be disposed on the first barrier insulating layer BIL1.

The second substrate SUB2 may be disposed on the second barrier insulating layer BIL2. The second substrate SUB2 may be a base substrate or a base part of the driver substrate DSB. The second substrate SUB2 may have a side surface tapered from the top surface.

The gate insulating layer GI may be disposed on the second substrate SUB2. The gate insulating layer GI may cover the bottom and side surfaces of the second substrate SUB2. The auxiliary line ALDL may be disposed on the gate insulating layer GI. The auxiliary line ALDL may extend in a layer between the gate insulating layer GI and the interlayer insulating layer ILD. The auxiliary line ALDL may be electrically connected to the lead line LDL, and the side surface of the auxiliary line ALDL may be in contact with the contact portion CTP. The driver substrate DSB may further include the auxiliary line ALDL, thereby maximizing contact efficiency between the lead line LDL and the contact portion CTP. The auxiliary line ALDL may be formed in the same process and contain the same material as the gate layer GTL of the display panel 100.

The interlayer insulating layer ILD may be disposed on the auxiliary line ALDL.

The lead line LDL may be disposed on the interlayer insulating layer ILD. The lead line LDL may extend along the bottom and side surfaces of the second substrate SUB2. The lead line LDL may be inserted into a contact hole provided in the interlayer insulating layer ILD to be brought into contact with the auxiliary line ALDL. The lead line LDL may electrically connect the bump electrode DLE of the display driver DIC to the pad part PAD of the display panel 100. The lead line LDL may be formed in the same process and contain the same material as the first source metal layer SDL1 of the display panel 100.

The end of the lead line LDL may be spaced apart from the end of each of the first and second barrier insulating layers BIL1 and BIL2, the gate insulating layer GI, the auxiliary line ALDL, and the interlayer insulating layer ILD. Here, the end of each of the first and second barrier insulating layers BIL1 and BIL2, the gate insulating layer GI, the auxiliary line ALDL, and the interlayer insulating layer ILD may be formed in the process of cutting and separating the display panel 100 from the driver substrate DSB. The end of the lead line LDL may be spaced apart from a cut line of the cutting process of the display panel 100 and the driver substrate DSB. Accordingly, damage to the lead line LDL may be avoided during the cutting process of the driver substrate DSB.

The protective part PRT may be disposed on the lead line LDL and the interlayer insulating layer ILD. The protective part PRT may be disposed below the driver substrate DSB to protect the driver substrate DSB.

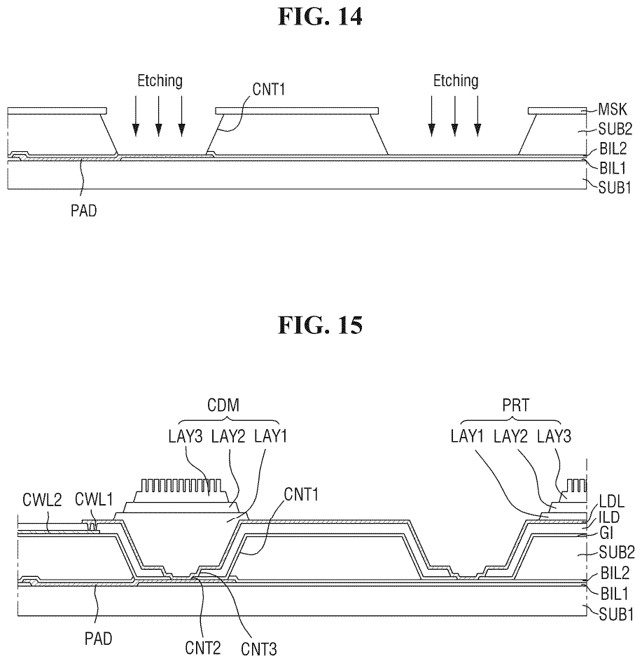

FIGS. 14 to 19 are schematic cross-sectional views illustrating a manufacturing process of a display device according to an embodiment.

In FIG. 14, the first substrate SUB1 may support the display device 10. The first substrate SUB1 may be a base substrate or a base part.

The first barrier insulating layer BIL1 may be disposed on the first substrate SUB1. The first barrier insulating layer BIL1 may include an inorganic layer capable of preventing permeation of air or moisture.

The pad part PAD may be disposed on the first barrier insulating layer BIL1. The pad part PAD may be inserted into a contact hole provided in the first barrier insulating layer BIL1.

The second barrier insulating layer BIL2 may be disposed on the pad part PAD. The second barrier insulating layer BIL2 may include an inorganic layer capable of preventing permeation of air or moisture.

The second substrate SUB2 may be disposed on the second barrier insulating layer BIL2. The second substrate SUB2 may be a base substrate or a base part.

A mask MSK may be disposed on the second substrate SUB2. An area of the second substrate SUB2 where the mask MSK is not disposed may be etched. Accordingly, the second substrate SUB2 may be patterned through a photo process using the mask MSK to form the first contact hole CNT1. For example, the mask MSK may be a hard mask containing indium zinc oxide (IZO), but the constituent material of the mask MSK is not limited thereto. The first contact hole CNT1 may be etched from the top surface of the second substrate SUB2 to penetrate the bottom surface of the second substrate SUB2. The upper area of the first contact hole CNT1 may be larger than the lower area of the first contact hole CNT1. During the process of forming the first contact hole CNT1, the top surface of the pad part PAD may be exposed.

In FIG. 15, the gate insulating layer GI may be disposed on the second substrate SUB2. The gate insulating layer GI may be inserted into the first contact hole CNT1 of the second substrate SUB2, and may be patterned to form the second contact hole CNT2. The second contact hole CNT2 may overlap the first contact hole CNT1. A part of the gate insulating layer GI may cover a part of the top surface of the pad part PAD exposed through the first contact hole CNT1. The area of the second contact hole CNT2 in plan view may be smaller than the area of the first contact hole CNT1 in plan view.

The second connection line CWL2 may be disposed on the gate insulating layer GI. The second connection line CWL2 may be formed in the same process and contain the same material as the gate layer GTL of the display area DA.

The interlayer insulating layer ILD may be disposed on the gate insulating layer GI. The interlayer insulating layer ILD may be inserted into the first contact hole CNT1 of the second substrate SUB2, and may be patterned to form the third contact hole CNT3. The third contact hole CNT3 may overlap the first and second contact holes CNT1 and CNT2. A part of the top surface of the gate insulating layer GI adjacent to the second contact hole CNT2 may be exposed through the third contact hole CNT3. In plan view, the area of the third contact hole CNT3 may be larger than the area of the second contact hole CNT2 and smaller than the area of the first contact hole CNT1.

The first connection line CWL1 may be disposed on the interlayer insulating layer ILD. The first connection line CWL1 may be formed in the same process and contain the same material as the first source metal layer SDL1 of the display area DA. An end of the first connection line CWL1 may be sequentially inserted into the first contact hole CNT1, the third contact hole CNT3, and the second contact hole CNT2 to be brought into contact with the top surface of the pad part PAD. The other end of the first connection line CWL1 may penetrate the interlayer insulating layer ILD to be brought into contact with the second connection line CWL2. The first connection line CWL1 may electrically connect the pad part PAD to the second connection line CWL2. The first connection line CWL1 may supply a data voltage or power voltage received from the pad part PAD to the second connection line CWL2.

The crack prevention portion CDM may include the first to third layers LAY1, LAY2, and LAY3. The first layer LAY1 of the crack prevention portion CDM may cover the top surface of the first connection line CWL1 inserted into the first to third contact holes CNT1, CNT2, and CNT3. The first layer LAY1 may fill the stepped portion caused by the first contact hole CNT1 of the second substrate SUB2. The first layer LAY1 may be formed in the same process and contain the same material as the first via layer VIA1.

The second layer LAY2 of the crack prevention portion CDM may be disposed on the first layer LAY1. The second layer LAY2 may be formed in the same process and contain the same material as the second via layer VIA2.

The third layer LAY3 of the crack prevention portion CDM may be disposed on the second layer LAY2. The third layer LAY3 may be formed in the same process and contain the same material as the pixel defining layer PDL.

The protective part PRT may include the first to third layers LAY1, LAY2, and LAY3. The first layer LAY1 of the protective part PRT may be disposed on the lead line LDL and the interlayer insulating layer ILD. The first layers LAY1 of the crack prevention portion CDM and the protective part PRT may contain the same material and be formed in the same process.

The second layer LAY2 of the protective part PRT may be disposed on the first layer LAY1. The second layers LAY2 of the crack prevention portion CDM and the protective part PRT may contain the same material and be formed in the same process.

The third layer LAY3 of the protective part PRT may be disposed on the second layer LAY2. The third layers LAY3 of the crack prevention portion CDM and the protective part PRT may contain the same material and be formed in the same process.

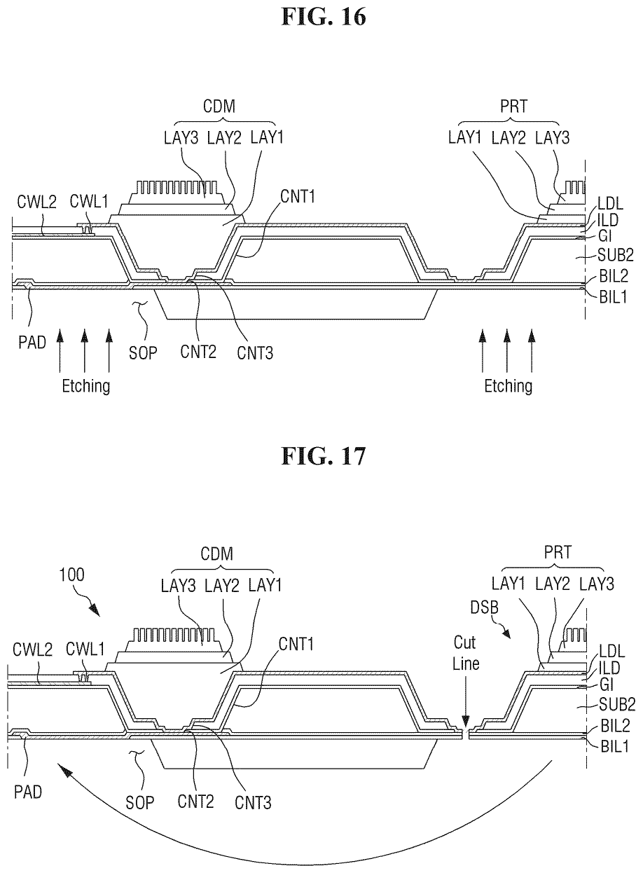

In FIG. 16, a surface of the first substrate SUB1 may be etched to form the opening SOP. A surface of the first substrate SUB1 may be subjected to at least one of a wet etching process, a dry etching process, a plasma etching process, and a laser etching process. The opening SOP may be provided in the first substrate SUB1 to expose the pad part PAD. An opening SOP may expose multiple pad parts PAD, but is not limited thereto.

The first substrate SUB1 supporting the driver substrate DSB may be etched. In a process prior to cutting and separating the driver substrate DSB from the display panel 100, the first substrate SUB1 supporting the driver substrate DSB may be removed in advance.

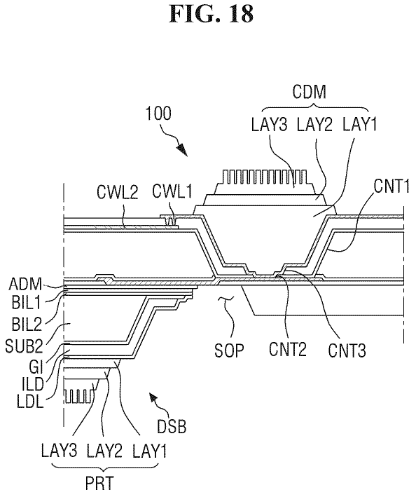

In FIG. 17, the display panel 100 and the driver substrate DSB may be cut and separated along a cut line. Thus, the driver substrate DSB may be manufactured to include some layers of the display panel 100 during the manufacturing process of the display panel 100. After being separated from the display panel 100, the driver substrate DSB may be turned upside down and inserted into the opening SOP of the first substrate SUB1.

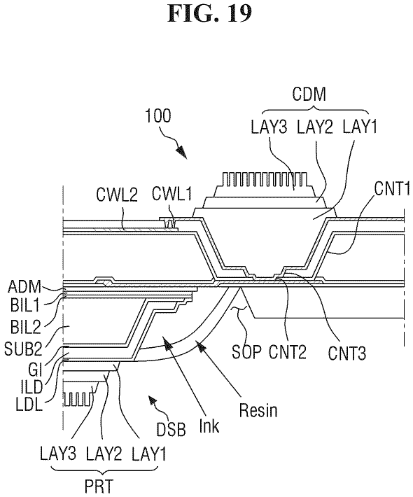

In FIG. 18, the driver substrate DSB may be attached to the bottom surfaces of the pad part PAD and the first barrier insulating layer BIL1 through an adhesive member ADM. The driver substrate DSB may be fixed to the bottom surface of the pad part PAD through the adhesive member ADM.

In FIG. 19, the contact portion CTP may cover the lead line LDL and the pad part PAD. The contact portion CTP may electrically connect the lead line LDL disposed on the side surface of the second substrate SUB2 to the bottom surface of the pad part PAD.

Conductive ink may be applied onto the lead line LDL and pad part PAD. The conductive ink may contain nanoparticles and polymers. The contact portion CTP may be formed by low temperature sintering of the conductive ink.

Sintered conductive ink, metal paste, or metal organic decomposition ink may cover the pad parts PAD and lead lines LDL inserted into an opening SOP at once, and cutting portions formed in a laser patterning process may separate contact portions CTP. The contact portion CTP may be spaced apart from the adjacent contact portion CTP by the cutting portions, and a contact portion CTP may electrically connect a pad part PAD to a lead line LDL.

The cover layer CRD may be disposed on the contact portion CTP to protect the contact portion CTP. The cover layer CRD may include an organic layer such as acryl resin, epoxy resin, phenolic resin, polyamide resin, polyimide resin and the like. The cover layer CRD may be formed by curing a monomer or applying a polymer.

Therefore, in the display device 10, the lead line LDL of the driver substrate DSB may be electrically connected to the pad part PAD through the contact portion CTP without using ultrasonic bonding or thermocompression bonding. In addition, the display device 10 may simplify the manufacturing process, thereby reducing manufacturing time and manufacturing cost.

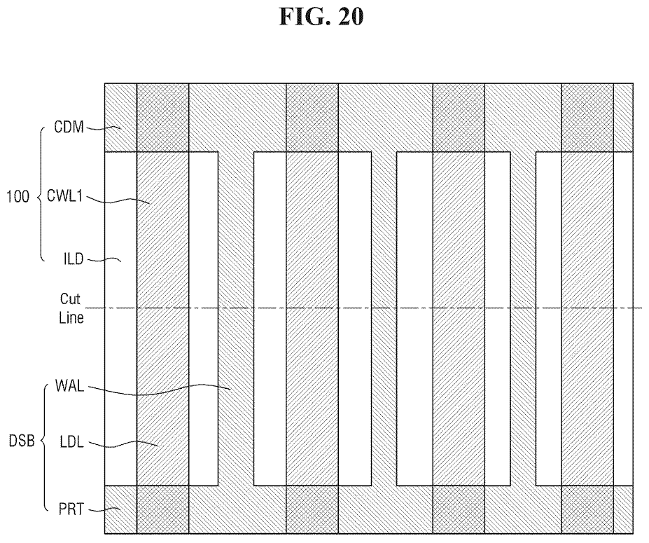

FIG. 20 is a schematic plan view illustrating an example of a cut line of a display panel and a driver substrate during the manufacturing process of a display device according to an embodiment. FIG. 20 is a plan view showing the manufacturing process of FIG. 17. The driver substrates DSB shown in FIGS. 7 to 12 may be manufactured according to the manufacturing process of FIG. 20.

Referring to FIG. 20, the first connection line CWL1 of the display panel 100 may be disposed on the interlayer insulating layer ILD. The lead line LDL of the driver substrate DSB may be disposed on the interlayer insulating layer ILD. Accordingly, the first connection line CWL1 and the lead line LDL may contain the same material and be formed in the same process.

The crack prevention portion CDM may be disposed on the first connection line CWL1 and the interlayer insulating layer ILD. The crack prevention portion CDM may be disposed at the outermost portion of the display panel 100 to prevent cracks in the display panel 100. The first and third encapsulation layers TFE1 and TFE3 and the planarization layer OC may be formed in an area surrounded by the crack prevention portion CDM.

The protective part PRT may be disposed on the lead line LDL and the interlayer insulating layer ILD. The protective part PRT may protect the driver substrate DSB by preventing permeation of moisture and external air.

Each of multiple partition walls WAL may be disposed between the lead lines LDL. The partition wall WAL may extend from the crack prevention portion CDM to the protective part PRT. The partition wall WAL may prevent the contact portions CTP covering the adjacent lead lines LDL from being in contact with each other. The contact portion CTP may be formed in an area provided by the partition wall WAL. Accordingly, a contact portion CTP may electrically connect a pad part PAD to a lead line LDL. The crack prevention portion CDM, the protective part PRT, and the partition wall WAL may contain the same material and be formed in the same process.

The display panel 100 and the driver substrate DSB may be cut and separated along a cut line.

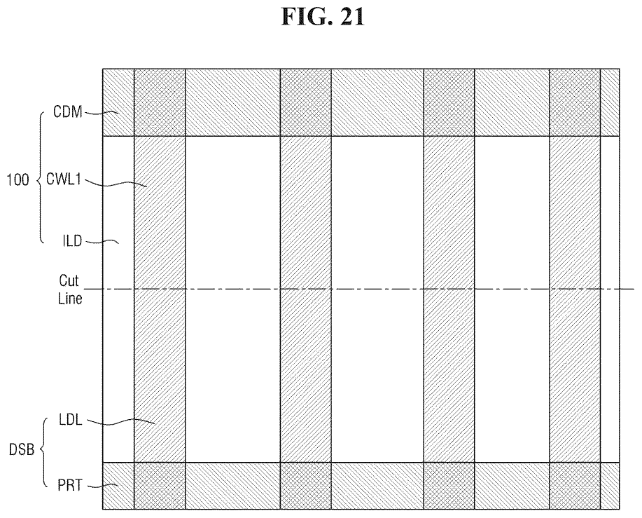

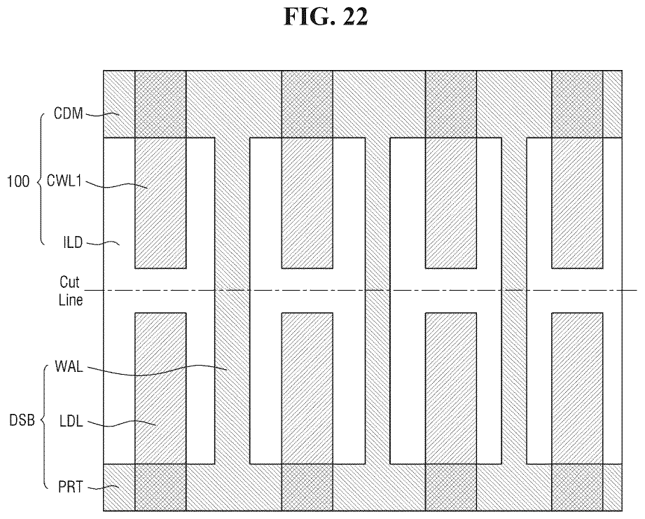

FIG. 21 is a schematic plan view illustrating another example of a cut line of a display panel and a driver substrate during the manufacturing process of a display device according to an embodiment. The display device of FIG. 21 omits the partition wall WAL from the display device of FIG. 20. The same configuration as the above-described configuration will be only briefly described or omitted.

Referring to FIG. 21, the display panel 100 and the driver substrate DSB may be cut and separated along a cut line.

After the driver substrate DSB is attached to the bottom surface of the pad part PAD through the adhesive member ADM, the sintered conductive ink or metal paste may cover the pad parts PAD and the lead lines LDL inserted into an opening SOP at once. The contact portions CTP may be separated to respectively correspond to the lead lines LDL through a laser patterning process. The contact portion CTP may be spaced apart from the adjacent contact portion CTP through a laser patterning process, and a contact portion CTP may electrically connect a pad part PAD to a lead line LDL.

FIG. 22 is a schematic plan view illustrating still another example of a cut line of a display panel and a driver substrate during the manufacturing process of a display device according to an embodiment. The display device of FIG. 22 differs from the display device of FIG. 20 in the configuration of the lead line LDL. The same configuration as the above-described configuration will be only briefly described or omitted. The driver substrate DSB shown in FIG. 13 may be manufactured according to the manufacturing process of FIG. 22.

Referring to FIG. 22, the first connection line CWL1 of the display panel 100 may be disposed on the interlayer insulating layer ILD. The lead line LDL of the driver substrate DSB may be disposed on the interlayer insulating layer ILD. Accordingly, the first connection line CWL1 and the lead line LDL may contain the same material and be formed in the same process.

The end of each of the first connection line CWL1 and the lead line LDL may be spaced apart from the cut line. Accordingly, damage to the lead line LDL may be avoided during the cutting process of the driver substrate DSB.

Each of multiple partition walls WAL may be disposed between the lead lines LDL. The partition wall WAL may extend from the crack prevention portion CDM to the protective part PRT. The partition wall WAL may prevent the contact portions CTP covering the adjacent lead lines LDL from being in contact with each other.

The display panel 100 and the driver substrate DSB may be cut and separated along a cut line.

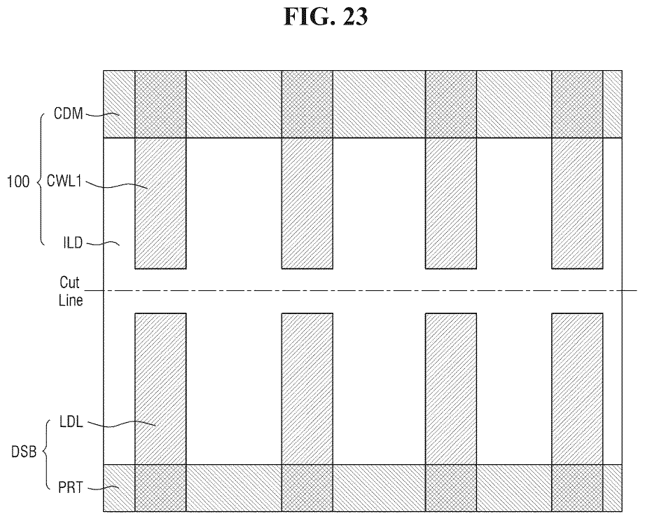

FIG. 23 is a schematic plan view illustrating still another example of a cut line of a display panel and a driver substrate during the manufacturing process of a display device according to an embodiment. The display device of FIG. 23 may omit the partition wall WAL from the display device of FIG. 22. The same configuration as the above-described configuration will be only briefly described or omitted.

Referring to FIG. 23, the display panel 100 and the driver substrate DSB may be cut and separated along a cut line.

After the driver substrate DSB is attached to the bottom surface of the pad part PAD through the adhesive member ADM, the sintered conductive ink or metal paste may cover the pad parts PAD and the lead lines LDL inserted into an opening SOP at once. The contact portions CTP may be separated to respectively correspond to the lead lines LDL through a laser patterning process. The contact portion CTP may be spaced apart from the adjacent contact portion CTP through a laser patterning process, and a contact portion CTP may electrically connect a pad part PAD to a lead line LDL.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a first substrate comprising an opening;
a pad part disposed on the first substrate and exposed through the opening;
a second substrate disposed on the pad part and comprising a first contact hole;
a first connection line disposed on the second substrate, and inserted into the first contact hole to be connected to the pad part;
a second connection line disposed in a layer between the second substrate and the first connection line and connected to the first connection line;
a pixel circuit electrically connected to the second connection line;
a driver substrate inserted into the opening of the first substrate, and comprising:
a base part disposed below the pad part and having a side surface tapered from a top surface; and
a lead line extending on a bottom surface and the side surface of the base part; and
a contact portion electrically connecting the pad part to the lead line.

2. The display device of claim 1, wherein the base part and the second substrate contain a same material and are formed in a same process.

3. The display device of claim 1, further comprising:
a gate insulating layer disposed on the second substrate and comprising a second contact hole overlapping the first contact hole; and
an interlayer insulating layer disposed on the gate insulating layer and comprising a third contact hole overlapping the first and second contact holes,
wherein the first connection line is inserted into the first to third contact holes to contact the pad part.

4. The display device of claim 1, wherein the contact portion is formed by sintering at least one of conductive ink, metal paste, and metal organic decomposition ink, the conductive ink containing at least one of silver (Ag), copper (Cu), aluminum (Al), and chromium (Cr).

5. The display device of claim 1, wherein the driver substrate further comprises:
a barrier insulating layer attached to a bottom surface of the pad part through an adhesive member;
a gate insulating layer disposed on the bottom surface and the side surface of the base part; and
an interlayer insulating layer disposed in a layer between the gate insulating layer and the lead line,
wherein the lead line and the first connection line contain a same material and are formed in a same process.

6. The display device of claim 1, wherein the driver substrate further comprises:
a gate insulating layer disposed on the bottom surface and side surface of the base part; and
an interlayer insulating layer disposed in a layer between the gate insulating layer and the lead line, wherein
the base part is attached to a bottom surface of the pad part through an adhesive member, and
the lead line and the first connection line contain a same material and are formed in a same process.

7. The display device of claim 1, wherein the driver substrate further comprises a barrier insulating layer attached to a bottom surface of the pad part through an adhesive member;
the lead line is directly disposed on the bottom surface and the side surface of the base part; and
the lead line and the first connection line contain a same material and are formed in a same process.

8. The display device of claim 1, wherein the driver substrate further comprises:
a barrier insulating layer attached to a bottom surface of the pad part through an adhesive member;
a gate insulating layer disposed on the bottom surface and the side surface of the base part; and
an interlayer insulating layer disposed in a layer between the gate insulating layer and the lead line,
wherein the lead line comprises:
a first line layer formed in a same process and containing a same material as the first connection line; and
a second line layer disposed on the first line layer.

9. The display device of claim 1, wherein the driver substrate further comprises:
a barrier insulating layer attached to a bottom surface of the pad part through an adhesive member; and
a gate insulating layer disposed on the bottom surface and the side surface of the base part,
wherein the lead line and the second connection line contain a same material and are formed in a same process.

10. The display device of claim 1, wherein the driver substrate further comprises:
a barrier insulating layer attached to a bottom surface of the pad part through an adhesive member;
an auxiliary line disposed in a layer between the barrier insulating layer and the base part;
a gate insulating layer disposed on the bottom surface and the side surface of the base part; and
an interlayer insulating layer disposed in a layer between the gate insulating layer and the lead line, wherein
the lead line and the first connection line contain a same material and are formed in a same process, and
the lead line contacts the auxiliary line.

11. The display device of claim 1, wherein
the driver substrate further comprises:
a barrier insulating layer attached to a bottom surface of the pad part through an adhesive member;
a gate insulating layer disposed on the bottom surface and the side surface of the base part;
an auxiliary line disposed on the gate insulating layer; and
an interlayer insulating layer disposed on the auxiliary line, wherein
the lead line and the first connection line contain a same material and are formed in a same process, and
the auxiliary line and the second connection line contain a same material and are formed in a same process.

12. The display device of claim 11, wherein
the lead line is inserted into a contact hole provided in the interlayer insulating layer to contact the auxiliary line, and
an end of the lead line is spaced apart from an end of the auxiliary line.

13. The display device of claim 12, further comprising:
a first via layer disposed on the pixel circuit;
a second via layer disposed on the first via layer;
pixel electrodes disposed on the second via layer; and
a pixel defining layer insulating the pixel electrodes,
wherein the driver substrate further comprises a protective part disposed on the lead line and the interlayer insulating layer, and formed in a same process and containing a same material as at least one of the first via layer, the second via layer, and the pixel defining layer.

14. The display device of claim 13, wherein
the driver substrate is disposed between the lead lines, and
the driver substrate further comprises a partition wall formed in a same process and containing a same material as the protective part.

15. A method of manufacturing a display device, comprising:
preparing a first substrate;
forming a pad part on the first substrate;
forming a base part and a second substrate on the pad part, the second substrate comprising a contact hole;
forming a connection line disposed on the second substrate and inserted into the contact hole, and a lead line disposed on the base part;
etching a lower portion of the first substrate to form an opening of the first substrate exposing the pad part, and removing the first substrate supporting the base part;
separating a driver substrate comprising the lead line and the base part by cutting along a cut line between the connection line and the lead line;
inserting the driver substrate into the opening to be disposed on a bottom surface of the pad part; and
forming a contact portion electrically connecting the lead line of the driver substrate to the pad part.

16. The method of claim 15, further comprising:
forming a barrier insulating layer on the first substrate;
forming a gate insulating layer on the second substrate and the base part; and
forming an interlayer insulating layer on the gate insulating layer,
wherein the separating of the driver substrate comprises separating the driver substrate comprising the barrier insulating layer, the base part, the gate insulating layer, the interlayer insulating layer, and the lead line.

17. The method of claim 15, further comprising:
forming a gate insulating layer on the second substrate and the base part; and
forming an interlayer insulating layer on the gate insulating layer,
wherein the separating of the driver substrate comprises separating the driver substrate comprising the base part, the gate insulating layer, the interlayer insulating layer, and the lead line.

18. The method of claim 15, further comprising:
forming a barrier insulating layer on the first substrate,
wherein the separating of the driver substrate comprises separating the driver substrate comprising the barrier insulating layer, the base part, and the lead line.

19. The method of claim 15, wherein the forming of the lead line comprises forming a lead line comprising a first line layer disposed on the base part and a second line layer disposed on the first line layer.

20. The method of claim 15, wherein the separating of the driver substrate comprises separating an end of the lead line from the cut line.
